(19) United States
(12) Patent Application Publication
(10) Pub. No.: US 2025/0166987 A1
(43) Pub. Date: May 22, 2025

(54) APPARATUS AND METHOD OF TREATING SUBSTRATE

(71) Applicant: SEMES CO., LTD., Cheonan-si (KR)

(72) Inventors: Yong Jun KIM, Anyang-si (KR); Tae Keun KIM, Siheung-si (KR); Kang Sul KIM, Hwaseong-si (KR); Jun Hee CHOI, Yongin-si (KR); Kyeong Min LEE, Hwaseong-si (KR)

(73) Assignee: SEMES CO., LTD., Cheonan-si (KR)

(21) Appl. No.: 18/954,889

(22) Filed: Nov. 21, 2024

(30) Foreign Application Priority Data
Nov. 22, 2023 (KR) 10-2023-0162939

(51) Int. Cl. H01L 21/02; B08B 3/04; B08B 3/08; B08B 5/00

(52) U.S. Cl. CPC H01L 21/02057; B08B 3/041; B08B 3/08; B08B 5/00

(57) ABSTRACT

Disclosed is a method of treating a substrate, the method including: a liquid treatment operation of treating a substrate by supplying a treatment solution to a rotating substrate to form a liquid film on the substrate; after the liquid treatment operation, a gas treatment operation of discharging gas to the substrate and removing an upper layer of the liquid film from the substrate; and after the gas treatment operation, a liquid film removal operation of removing a lower layer in the liquid film on the substrate.

### CROSS-REFERENCE TO RELATED APPLICATIONS

This application claims priority to and the benefit of Korean Patent Application No. 10-2023-0162939 filed in the Korean Intellectual Property Office on Nov. 22, 2023, the entire contents of which are incorporated herein by reference.

### TECHNICAL FIELD

The present invention relates to a substrate treating method and a substrate treating apparatus, and more particularly to a substrate treating apparatus for treating a substrate by supplying a cleaning solution to a rotating substrate and discharging gas.

### BACKGROUND ART

A semiconductor process includes a process of cleaning a thin film, foreign substances, particles, and the like on a substrate. This is accomplished by placing a substrate on a spin head with a patterned side facing up or down, and supplying a treatment solution onto the substrate while the spin head is rotated.

The cleaning process is accomplished by supplying a cleaning solution. Deionized water or pure water is commonly used as the cleaning solution. Typically, the substrate is rotated at a high speed during the cleaning process to remove particles that are generated during the supply of the cleaning solution to the substrate from the substrate. However, the high-speed rotation of the substrate reduces a thickness of a liquid film of the cleaning solution on the substrate, which causes particles suspended in the liquid film of the cleaning solution to be located adjacent to the substrate and to be reattached to the substrate.

### SUMMARY OF THE INVENTION

The present invention has been made in an effort to prevent re-adsorption of impurities during a cleaning process.

The present invention has been made in an effort to efficiently remove impurities even when the substrate is rotated at a low speed.

The problem to be solved by the present invention is not limited to the above-mentioned problems, and the problems not mentioned will be clearly understood by those skilled in the art from the descriptions below.

An exemplary embodiment of the present invention provides a method of treating a substrate, the method including: a liquid treatment operation of treating a substrate by supplying a treatment solution to a rotating substrate to form a liquid film on the substrate; after the liquid treatment operation, a gas treatment operation of discharging gas to the substrate and removing an upper layer of the liquid film from the substrate; and after the gas treatment operation, a liquid film removal operation of removing a lower layer of the liquid film on the substrate

According to the exemplary embodiment of the present invention, a rotation speed of the substrate in the liquid treatment operation may be a speed at which foreign substances residual on the substrate are suspended and retained in the upper layer.

According to the exemplary embodiment of the present invention, in the gas treatment operation, the gas may be discharged at a pressure that removes only the upper layer of the liquid film.

According to the exemplary embodiment of the present invention, in the gas treatment operation, the gas may be discharged while moving an impingement point of the gas from a center region of the substrate toward an edge region.

According to the exemplary embodiment of the present invention, in the gas treatment operation, the gas may be discharged to the substrate in a downwardly inclined direction toward the edge.

According to the exemplary embodiment of the present invention, the method may further include a chemical treatment operation of treating the substrate with a chemical by supplying the chemical prior to the liquid treatment operation, in which the chemical treatment operation may include supplying the chemical to the rotating substrate, and a rotation speed of the substrate in the gas treatment operation may be lower than a rotation speed of the substrate in the chemical treatment operation.

According to the exemplary embodiment of the present invention, the liquid film removal operation may include supplying a solvent more volatile than the treatment solution to the substrate to substitute the lower layer of the liquid film on the substrate with the solvent.

According to the exemplary embodiment of the present invention, the liquid film removal operation may be an operation of drying the substrate.

According to the exemplary embodiment of the present invention, the liquid film removal operation may include drying the substrate by rotating the substrate at a speed higher than a rotation speed of the substrate in the gas treatment operation.

According to the exemplary embodiment of the present invention, gas may be discharged during the liquid film removal operation, and the gas may be discharged at a pressure that removes the lower layer of the liquid film.

According to the exemplary embodiment of the present invention, in the liquid film removal operation, the gas may be discharged at a stronger discharge pressure than that in the gas treatment operation.

According to the exemplary embodiment of the present invention, the treatment solution may be pure or deionized water (DIW), and the gas may be nitrogen, inert gas or air.

Another exemplary embodiment of the present invention provides a substrate treating apparatus including: a chamber for providing a treatment space for treating a substrate; a support unit for supporting and rotating the substrate in the treatment space; a treatment solution nozzle for supplying a treatment solution to the substrate supported on the support unit; a gas nozzle located adjacent to an upper surface of the substrate, and discharging gas onto the substrate supported on the support unit; a driver for moving the gas nozzle such that an impingement point of the gas discharged from the gas nozzle onto the substrate supported on the support unit is moved; and a controller for controlling the support unit, the treatment solution nozzle, the gas nozzle, and the driver, in which the controller controls the support unit, the treatment solution nozzle, the gas nozzle, and the driver so that a liquid treatment operation of treating a substrate by supplying a treatment solution to a rotating substrate to form a liquid film on the substrate, after the liquid treatment operation, a gas treatment operation of discharging gas to the substrate and removing an upper layer of the liquid film from the substrate, and after the gas treatment operation, a liquid film removal operation of removing a lower layer of the liquid film from the substrate are sequentially performed, in the liquid treatment operation, a rotation speed of the substrate is a speed at which foreign substances residual on the substrate are suspended and retained in the upper layer, and in the gas treatment operation, a discharge pressure of the gas is set to remove only the upper layer of the liquid film.

According to the exemplary embodiment of the present invention, the controller may control so that, in the gas treatment operation, the gas is discharged to the substrate in a downwardly inclined direction toward the edge.

According to the exemplary embodiment of the present invention, the controller may control a chemical treatment operation of treating the substrate with a chemical by supplying the chemical to be performed prior to the liquid treatment operation, and control so that the chemical is supplied to the rotating substrate during the chemical treatment operation, and a rotation speed of the substrate during the gas treatment operation may be lower than a rotation speed of the substrate in the chemical treatment operation.

According to the exemplary embodiment of the present invention, the controller may control so that, during the liquid film removal operation, a solvent more volatile than the treatment solution is supplied to the substrate to substitute the lower layer of the liquid film on the substrate with the solvent.

According to the exemplary embodiment of the present invention, the liquid film removal operation may be an operation of drying the substrate, and the controller may control so that the substrate is rotated at a speed higher than a rotation speed of the substrate in the gas treatment operation during the drying of the substrate.

Still another exemplary embodiment of the present invention provides a method of treating a substrate, the method including: a chemical treatment operation of treating a substrate with a chemical by supplying the chemical to a rotating substrate; a liquid treatment operation of treating the substrate by supplying a treatment solution to the rotating substrate to form a liquid film on the substrate; after the liquid treatment operation, a gas treatment operation of discharging gas to the substrate and removing an upper layer of the liquid film from the substrate; and after the gas treatment operation, a liquid film removal operation of removing a lower layer of the liquid film from the substrate, in which in the liquid treatment operation, a rotational speed of the substrate is a speed at which foreign substances residual on the substrate are suspended and retained in the upper layer, and in the gas treatment operation, the gas is discharged at a pressure that removes only the upper layer of the liquid film while moving an impingement point of the gas from a center region of the substrate toward an edge region.

According to the exemplary embodiment of the present invention, the liquid film removal operation may include supplying a solvent more volatile than the treatment solution to the substrate to substitute the lower layer of the liquid film on the substrate with the solvent.

According to the exemplary embodiment of the present invention, the gas treatment operation may include discharging the gas to the substrate in a downwardly inclined direction toward the edge, and rotating the substrate at a rotation speed of the substrate lower than a rotation speed of the substrate in the chemical treatment operation, and the liquid film removal operation may include rotating the substrate at a rotation speed of the substrate greater than a rotation speed of the substrate in the gas treatment operation, and drying the substrate by discharging the gas at a pressure at which the lower layer of the liquid film is removed.

According to the exemplary embodiment of the present invention, it is possible to prevent re-adsorption of impurities during the cleaning process.

Further, according to the exemplary embodiment of the present invention, it is possible to efficiently remove impurities even when the substrate is rotated at low speeds.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a drawing illustrating a substrate treating apparatus according to an exemplary embodiment of the present invention.

FIG. 2 is a cross-sectional view illustrating a cross-section of a liquid treating chamber of FIG. 1.

FIG. 3 is a flowchart illustrating a method of treating a substrate with the liquid treating chamber of FIG. 2.

FIG. 4 is a diagram schematically illustrating performing a chemical treatment operation of FIG. 3.

FIGS. 5 to 7 are diagrams schematically illustrating performing a liquid treatment operation of FIG. 3.

FIGS. 8 to 10 are diagrams schematically illustrating performing a gas treatment operation of FIG. 3.

FIGS. 11 to 13 are diagrams schematically illustrating a solvent substitution operation of a liquid film removal operation of FIG. 3.

FIGS. 14 to 16 are diagrams schematically illustrating a substrate drying operation of FIG. 3.

FIG. 17 is a cross-sectional view of one exemplary embodiment of a supercritical chamber used for the substrate drying operation during the liquid film removal operation of FIG. 3.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

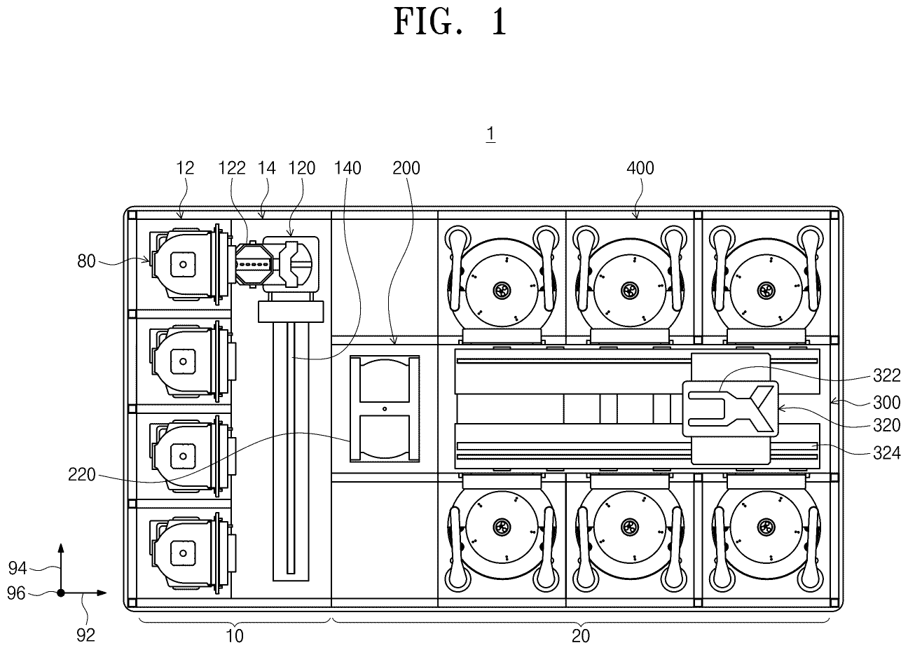

FIG. 1 is a top plan view schematically illustrating a substrate treating apparatus according to an exemplary embodiment of the present invention.

Referring to FIG. 1, a substrate treating apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transport means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forward and backward independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on both sides of the transfer chamber 300. At each of both sides of the transfer device 300, the liquid treating devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forward and backward, rotatable about the third direction 96, and movable along the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

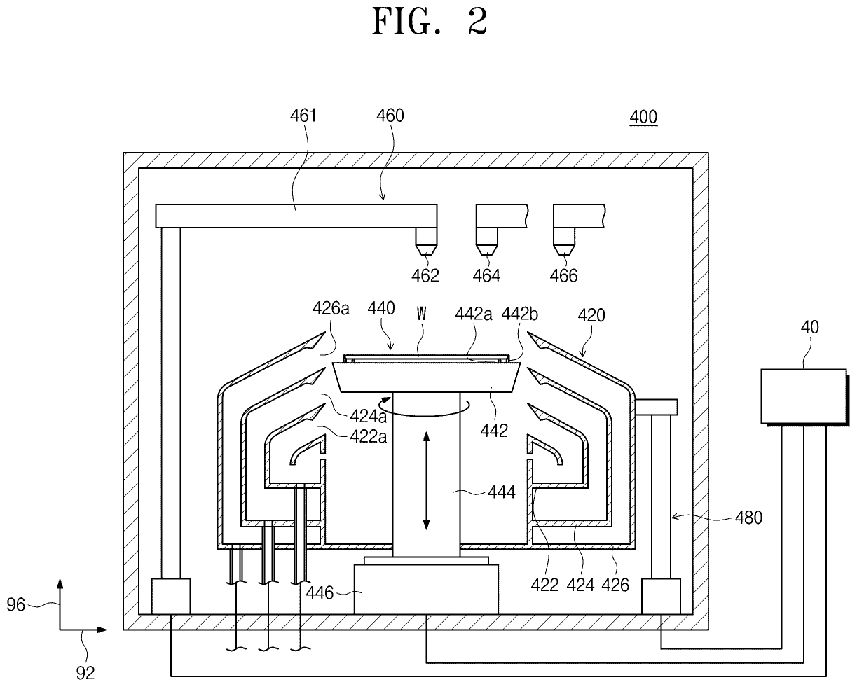

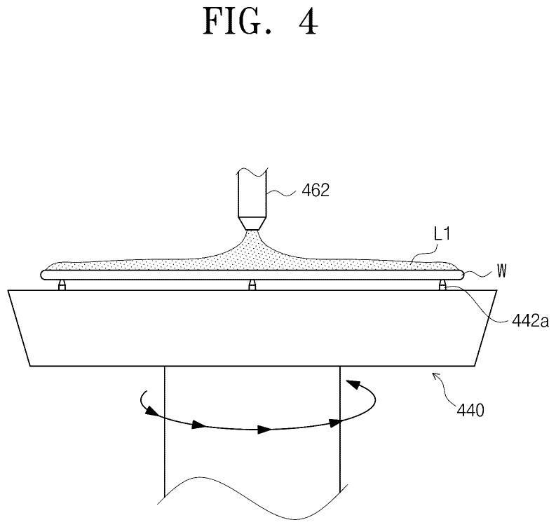

FIG. 2 is a diagram schematically illustrating an exemplary embodiment of the liquid treating chamber 400 of FIG. 1. Referring to FIG. 4, the liquid treating chamber 400 has a housing 410, a cup 420, a support unit 440, a nozzle unit 460, a lifting unit 480, a supply unit, and a controller.

The housing 410 is provided in a generally rectangular parallelepiped shape. The cup 420, the support unit 440, and the liquid supply unit 460 are disposed in the housing 410.

The cup 420 has a treatment space with an open top, and the substrate W is liquid-treated in the treatment space. The support unit 440 supports the substrate W in the treatment space. The liquid supply unit 460 supplies the liquid onto the substrate W supported by the support unit 440. The liquid may be provided in a plurality of types, and may be sequentially supplied onto the substrate W. The lifting unit 480 adjusts a relative height between the cup 420 and the support unit 440.

According to the example, the cup 420 includes a plurality of collection containers 422, 424, and 426. Each of the collection containers 422, 424, and 426 has a collection space of collecting the liquid used for the treating of the substrate. Each of the collection containers 422, 424, and 426 is provided in a ring shape surrounding the support unit 440. When the liquid treatment process is in progress, the treatment solution scattered by the rotation of the substrate W is introduced into the collection space through inlets 422a, 424a, and 426a of the respective collection containers 422, 424, and 426. According to the example, the cup 420 includes a first collection container 422, a second collection container 424, and a third collection container 426. The first collection container 422 is disposed to surround the support unit 440, the second collection container 424 is disposed to surround the first collection container 422, and the third collection container 426 is disposed to surround the second collection container 424. A second inlet 424a, which introduces the liquid into the second collection container 424, may be located above a first inlet 422a, which introduces the liquid into the first collection container 422, and a third inlet 426a, which introduces the liquid into the third collection container 426, may be located above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The drive shaft 444 is driven by a driver 446, is connected to the center of the bottom surface of the substrate W, and rotates the support plate 442 with respect to the central axis thereof.

The nozzle unit 460 has a first nozzle 462, a second nozzle 464, and a third nozzle 466. The first nozzle 462 supplies the treatment solution onto the substrate W. The treatment solution may be chemical. The second nozzle 464 supplies water onto the substrate W. The water may be pure water or deionized water. The third nozzle 466 discharges the gas onto the substrate. The gas may be nitrogen, inert gas, or air. The third nozzle 466 may dispense gas at a downward slope in a direction toward an edge region of the substrate W. Optionally, the gas may be discharged perpendicular to the substrate W. Additionally, the third nozzle 466 may be moved while discharging the gas.

The first nozzle 462, the second nozzle 464, and the third nozzle 466 are each supported on different arms 461, and the arms 461 may be moved independently by a driver. Optionally, the first nozzle 462, the second nozzle 464, and the third nozzle 466 may be mounted on the same arm and moved simultaneously.

Optionally, the nozzle unit may further include one or more nozzles in addition to the first nozzle 462, the second nozzle 464, and the third nozzle 466. Additional nozzles may supply different types of treatment solutions to the substrate. For example, the other type of treatment solution may be an acid solution or a base solution for removing foreign substances on the substrate.

The lifting unit 480 moves the cup 420 in the vertical direction. By the vertical movement of the cup 420, a relative height between the cup 420 and the substrate W is changed. Accordingly, since the collection containers 422, 424, and 426 for collecting the treatment solution are changed according to the type of the liquid supplied to the substrate W, the liquids may be separated and collected. Unlike the above, the cup 420 may be fixedly installed, and the lifting unit 480 may move the support unit 440 in the vertical direction.

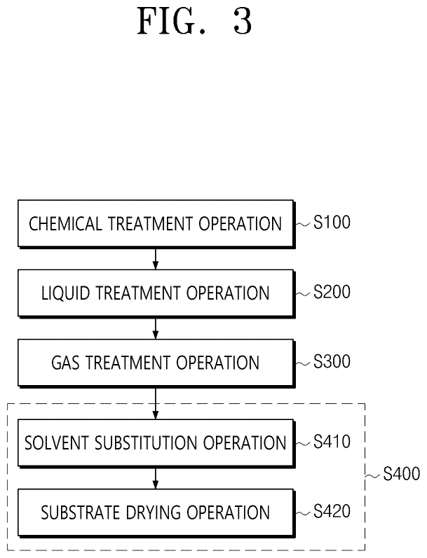

FIG. 3 is a flowchart illustrating a method of cleaning a substrate with the liquid treating chamber of FIG. 2, and FIG. 4 is a diagram schematically illustrating performing a chemical treatment operation of FIG. 3. The absolute and relative thicknesses of the substrate and the liquid film and the size of the impurities suspended in the liquid film are exaggerated for illustration purposes and some of the configurations of the present invention are omitted.

Referring to FIG. 4, a method of treating a substrate according to an exemplary embodiment of the present invention includes a chemical treatment operation S100, a liquid treatment operation S200, a gas treatment operation S300, and a liquid film removal operation S400.

FIG. 4 is a diagram schematically illustrating the chemical treatment operation. Referring to FIG. 4, in the chemical treatment operation S100, the substrate W is chemically treated. The first nozzle 462 supplies a chemical onto the substrate. The chemical may be supplied while the substrate W is being rotated by the support unit 440. Alternatively, the chemical may be supplied onto the substrate W first and then the substrate W may be rotated. As the substrate W rotates, the chemical forms a liquid film L1 on the substrate W. The liquid film L1 is formed on the front face of the substrate W. Thereby, the substrate is chemically treated. In the chemical treatment operation S100, the substrate W may be rotated faster than the rotation speed of the substrate in the liquid treatment operation W to be described later. In one example, the substrate W may be rotated at 1000 to 1500 RPM in the chemical treatment operation S100.

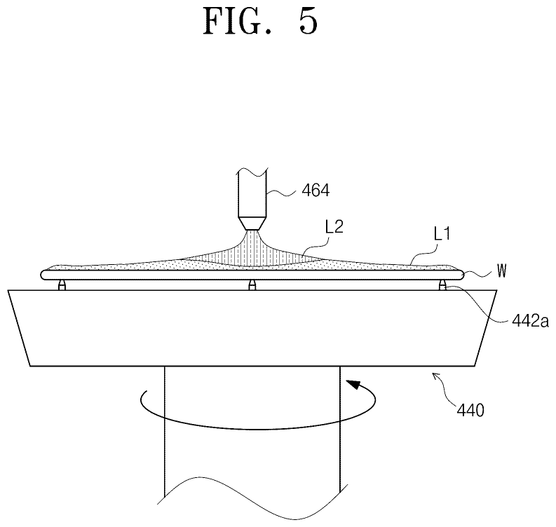

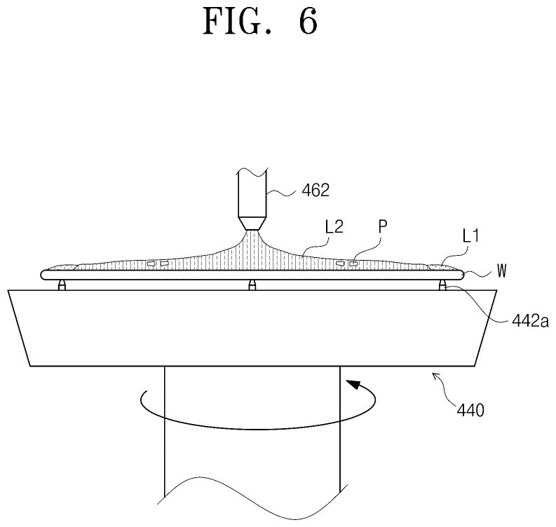

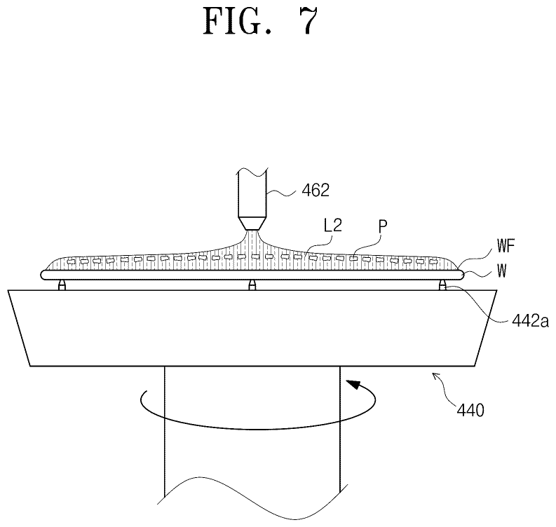

After the chemical treatment operation S100 is completed, the liquid treatment operation S200 is performed. FIGS. 5 to 7 are diagrams schematically illustrating the liquid treatment operation over time. Referring to FIGS. 5 to 7, in the liquid treatment operation S200, a treatment solution is supplied to the substrate. The second nozzle 464 supplies the treatment solution onto the substrate. The treatment solution may be water, as described above. The treatment solution may be supplied while the substrate W is being rotated by the support unit 440. Alternatively, the treatment solution may be supplied to the substrate W first and the substrate W may be rotated thereafter. In the liquid treatment operation S200, the chemical remaining on the substrate W are removed, and a liquid film L2 of the treatment solution is formed on the substrate. In addition, in the liquid treatment operation S200, a relatively large amount of the particles P remaining on the substrate W are retained in an upper layer in the liquid film. The liquid film L2 is formed on a front face Wf of the substrate W. In one exemplary embodiment, the substrate W is rotated at a speed that keeps the particles P remaining in the liquid film L2 in the upper layer of the liquid film L2 by suspending the particles P in the liquid film. This may be accomplished by rotating the substrate W at a slow speed during the liquid treatment operation S200. In the liquid treatment operation S200, the substrate W may be rotated at a slower speed than the rotation speed of the substrate W in the chemical treatment operation S200. In one example, in the chemical treatment operation S100, the substrate W may be rotated at 100 to 500 RPM.

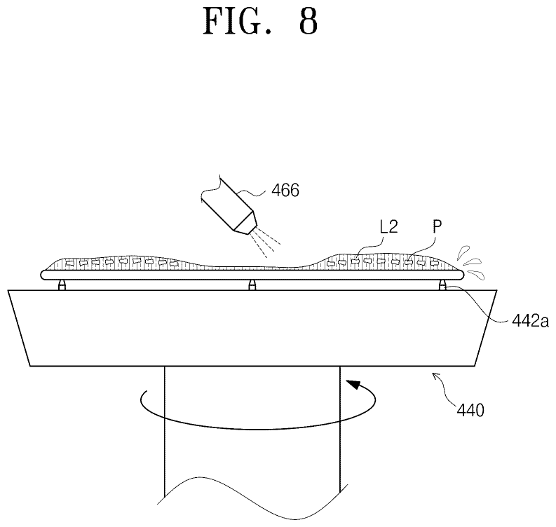

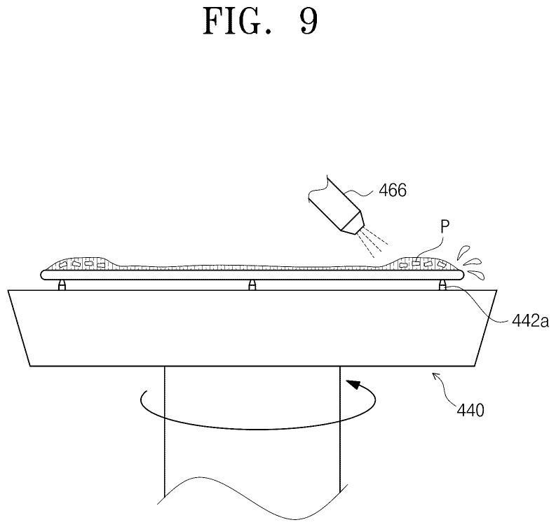

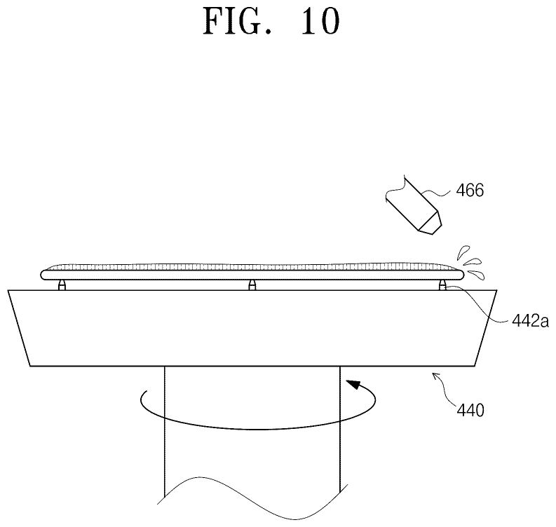

After the liquid treatment operation S200 is completed, the gas treatment operation S300 is performed. FIGS. 8 to 10 are diagrams schematically illustrating the gas treatment operation over time. Referring to FIGS. 8 to 10, during the gas treatment operation S300, gas is discharged onto the substrate W to remove only the upper layer of the liquid film L2. During the gas treatment operation S300, the substrate W may be rotated at a slower speed than the rotation speed of the substrate W in the chemical treatment operation S100. For example, the substrate W may rotate at the same speed as the rotation speed of the substrate W in the liquid treatment operation S200. The third nozzle 466 discharges gas onto the substrate W. The third nozzle 466 discharges gas at a pressure that removes only the upper layer of the liquid film L2. Additionally, during the discharge of the gas from the third nozzle 466, the third nozzle 466 may be moved from a center region of the substrate W to an edge region. Optionally, the third nozzle 466 may reciprocate between the center region and the edge region of the substrate W. Thereby, the upper layer of the liquid film L2 may be removed. Since impurities are suspended in the upper layer of the liquid film L2, when the upper layer of the liquid film L2 is removed, a large amount of impurities may also be removed.

After the gas treatment operation S300 is completed, the liquid film removal operation S400 is performed. The liquid film removal operation includes a solvent substitution operation S410 and a substrate drying operation S420.

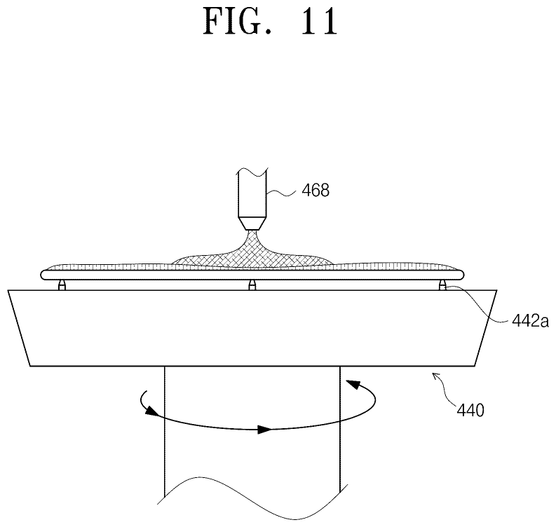

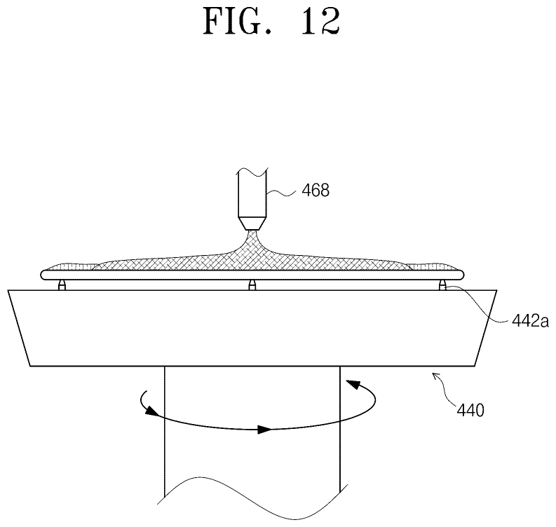

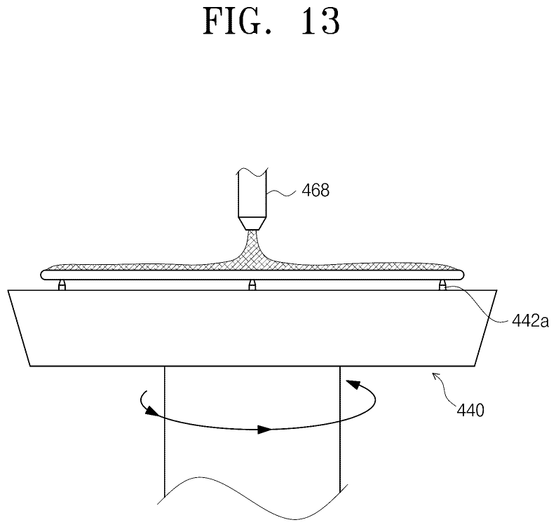

FIGS. 11 to 13 are diagrams schematically illustrating a solvent substitution operation of a liquid film removal operation of FIG. 3. Referring to FIG. 11, after the gas treatment operation S300, a solvent substitution operation S410 is performed. During the solvent substitution operation S410, a solvent is supplied to the substrate W. The solvent may be supplied by an additionally provided fourth nozzle 468. The supplied solvent substitutes for the lower layer of the residual liquid film L2. Thereby, the treatment solution may be removed from the substrate W. The solvent may be an organic solvent that is more volatile than the treatment solution. In one example, the solvent may be isopropyl alcohol (IPA). Since the solvent is highly volatile, some of the supplied solvent may volatilize and be removed from the substrate W.

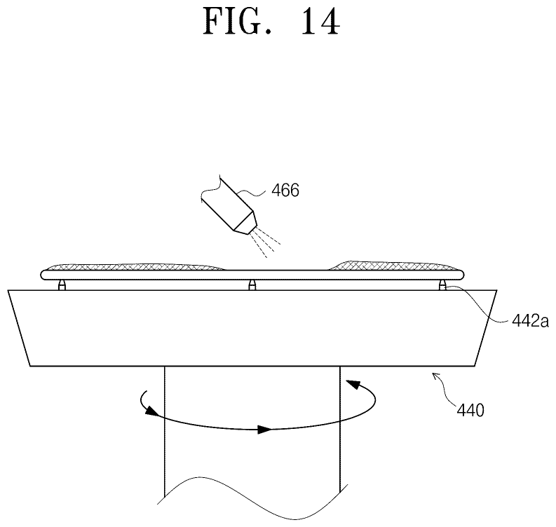

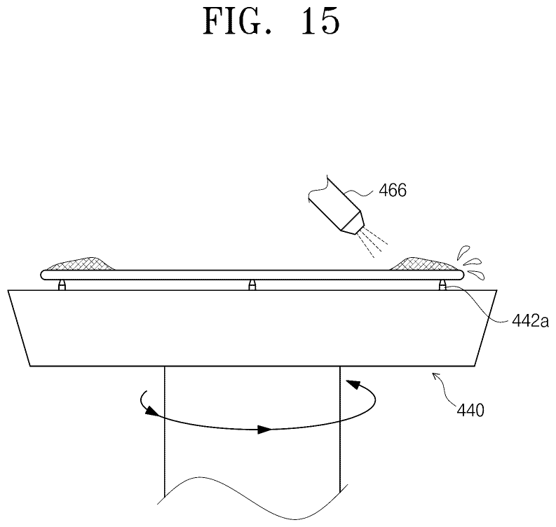

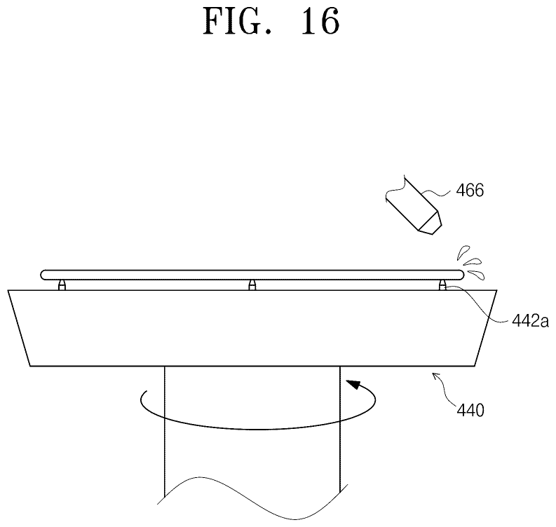

After the solvent substitution operation S410, a substrate drying operation S420 is performed. FIGS. 14 to 16 are diagrams schematically illustrating the substrate drying operation of FIG. 3. In the substrate drying operation S420, the residual liquid film L2 is removed. The liquid film L2 may be removed by rotating and gas-treating the substrate W. The rotation speed may be faster than the rotation speed in the gas treatment operation S300. Also, the rotation speed may be slower than the rotation speed in the chemical treatment operation S100. In one example, the rotation speed may be 500 to 1000 RPM. During the substrate drying operation S420, gas is sprayed onto the substrate W from the third nozzle 466. During the substrate drying operation S420, the third nozzle 466 may discharge gas as it moves from the center region of the substrate W to the edge region. The liquid film L2 may be removed from the substrate W by centrifugal force generated by rotation of the substrate W and the gas treatment.

Typically, when a substrate is rotated and cleaned, a treatment solution is supplied to the substrate W and the substrate is rotated at a high speed to remove the treatment solution. The treatment solution is supplied to the substrate W, and impurities are suspended in the treatment solution and are removed from the substrate W by high-speed rotation. However, when the substrate is rotated at a high speed, the liquid film L formed has a small thickness, so that the impurities suspended in the treatment solution may be reabsorbed onto the substrate W because the impurities suspended in the treatment solution are close to the substrate W is close.

However, according to the exemplary embodiment of the present invention, a relatively thick liquid film L may be formed because the substrate is rotated at a relatively low speed. Accordingly, the distance between the impurities suspended in the liquid film L and the substrate may be increased to prevent the impurities from being reabsorbed onto the substrate. Furthermore, by discharging gas from the third nozzle, the impurities suspended in the liquid film L may be removed from the substrate even when the substrate rotates at a low speed.

In the example described above, the present invention has been described based on the case where the liquid film removal operation includes the solvent replacement operation S410 and the substrate drying operation S420 as an example. However, without limitation, the solvent substitution operation S410 may be omitted and the drying operation S420 may be performed after the gas treatment operation S300.

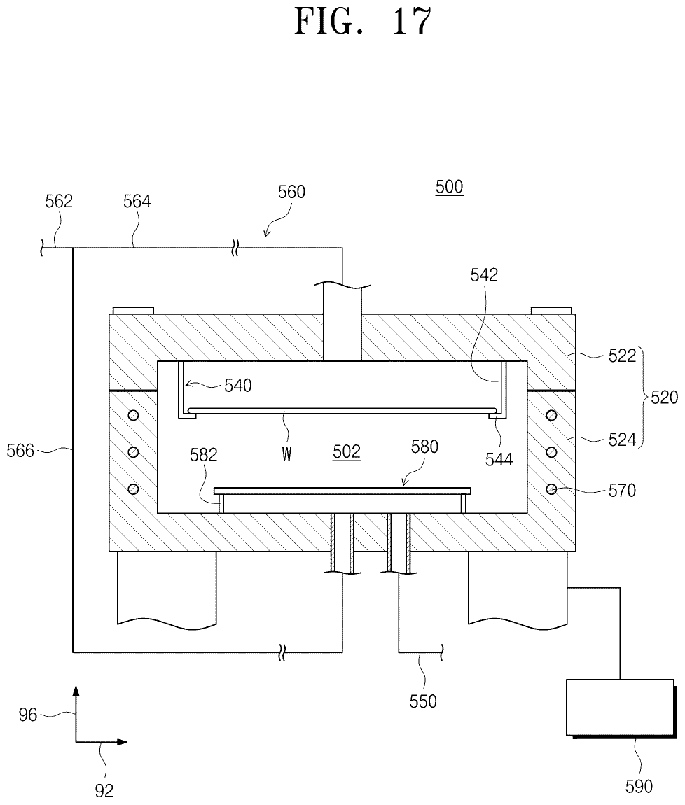

Also, in the above-described example, the substrate W is rotated during the substrate drying operation S420, and the substrate W is dried by spraying gas. However, it is not limited to this, and a drying chamber for drying the substrate may be provided separately, as shown in FIG. 17. FIG. 17 is a cross-sectional view of the drying chamber drying the substrate. In one example, the drying chamber may be a supercritical chamber in which the substrate W is treated with a supercritical fluid. The supercritical chamber dries the substrate W by using the supercritical fluid. Referring to FIG. 17, the supercritical chamber 500 includes a body 520, a support body 540, a fluid supply unit 560, and a blocking plate 580. The body 520 provides an internal space 502 in which the drying process is performed. The support body 540 supports the substrate W in the internal space 502 of the body 520. The fluid supply unit 560 supplies a drying fluid to the interior space 502 of the body 520. The blocking plate 580 may prevent drying fluid supplied through the lower branch line 566 from being discharged directly toward the substrate W and damaging the substrate W.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

1. A method of treating a substrate, the method comprising:
a liquid treatment operation of treating a substrate by supplying a treatment solution to a rotating substrate to form a liquid film on the substrate;
after the liquid treatment operation, a gas treatment operation of discharging gas to the substrate and removing an upper layer of the liquid film from the substrate; and
after the gas treatment operation, a liquid film removal operation of removing a lower layer in the liquid film on the substrate.

2. The method of claim 1, wherein a rotation speed of the substrate in the liquid treatment operation is a speed at which foreign substances residual on the substrate are suspended and retained in the upper layer.

3. The method of claim 2, wherein in the gas treatment operation, the gas is discharged at a pressure that removes only the upper layer of the liquid film

4. The method of claim 1, wherein in the gas treatment operation, the gas is discharged while moving an impingement point of the gas from a center region of the substrate toward an edge region.

5. The method of claim 3, wherein in the gas treatment operation, the gas is discharged to the substrate in a downwardly inclined direction toward the edge.

6. The method of claim 2, further comprising:
a chemical treatment operation of treating the substrate with a chemical by supplying the chemical prior to the liquid treatment operation,
wherein the chemical treatment operation includes supplying the chemical to the rotating substrate, and
a rotation speed of the substrate in the gas treatment operation is lower than a rotation speed of the substrate in the chemical treatment operation.

7. The method of claim 1, wherein the liquid film removal operation includes supplying a solvent more volatile than the treatment solution to the substrate to substitute the lower layer of the liquid film on the substrate with the solvent.

8. The method of claim 2, wherein the liquid film removal operation is an operation of drying the substrate.

9. The method of claim 8, wherein the liquid film removal operation includes drying the substrate by rotating the substrate at a speed higher than a rotation speed of the substrate in the gas treatment operation.

10. The method of claim 9, wherein gas is discharged during the liquid film removal operation, and
the gas is discharged at a pressure that removes the lower layer of the liquid film is removed.

11. The method of claim 10, wherein in the liquid film removal operation, the gas is discharged at a stronger discharge pressure than that in the gas treatment operation.

12. The method of claim 1, wherein the treatment solution is pure or deionized water (DIW), and
the gas is nitrogen, inert gas or air.

13. (canceled)

14. (canceled)

15. (canceled)

16. (canceled)

17. (canceled)

18. A method of treating a substrate, the method comprising:
a chemical treatment operation of treating a substrate with a chemical by supplying the chemical to a rotating substrate;
a liquid treatment operation of treating the substrate by supplying a treatment solution to the rotating substrate to form a liquid film on the substrate;
after the liquid treatment operation, a gas treatment operation of discharging gas to the substrate and removing an upper layer of the liquid film from the substrate; and
after the gas treatment operation, a liquid film removal operation of removing a lower layer of the liquid film from the substrate,
wherein in the liquid treatment operation, a rotational speed of the substrate is a speed at which foreign substances residual on the substrate are suspended and retained in the upper layer, and
in the gas treatment operation, the gas is discharged at a pressure that reomoves only the upper layer of the liquid film while moving an impingement point of the gas from a center region of the substrate toward an edge region.

19. The method of claim 18, wherein the liquid film removal operation includes supplying a solvent more volatile than the treatment solution to the substrate to substitute the lower layer of the liquid film on the substrate with the solvent.

20. The method of claim 18, wherein the gas treatment operation includes discharging the gas to the substrate in a downwardly inclined direction toward the edge, and rotating the substrate at a rotation speed of the substrate lower than a rotation speed of the substrate in the chemical treatment operation, and
substrate greater than a rotation speed of the substrate in the gas treatment operation, and drying the substrate by discharging the gas at a pressure that removes the lower layer in the liquid film.
